(19) United States
(12) Patent Application Publication
(10) Pub. No.: US 2022/0199854 A1
(43) Pub. Date: Jun. 23, 2022

(54) METHOD FOR PRODUCING GROUP 13 ELEMENT NITRIDE CRYSTAL LAYER, AND SEED CRYSTAL SUBSTRATE

(71) Applicant: NGK INSULATORS, LTD., Nagoya-city (JP)

(72) Inventors: Masahiro SAKAI, NAGOYA-CITY (JP); Takayuki HIRAO, NISSHIN-CITY (JP); Hirokazu NAKANISHI, NAGOYA-CITY (JP); Mikiya ICHIMURA, ICHINOMIYA-CITY (JP); Takanao SHIMODAIRA, NAGOYA-CITY (JP); Takashi YOSHINO, AMA-CITY (JP); Katsuhiro IMAI, NAGOYA-CITY (JP); Yoshitaka KURAOKA, OKAZAKI-CITY (JP)

(21) Appl. No.: 17/691,434

(22) Filed: Mar. 10, 2022

Related U.S. Application Data
(63) Continuation of application No. PCT/JP2020/027802, filed on Jul. 17, 2020.

(30) Foreign Application Priority Data
Sep. 11, 2019 (JP) 2019-165026

(51) Int. Cl. H01L 33/00; C30B 29/38; H01L 33/32

(52) U.S. Cl. CPC H01L 33/0075; H01L 33/32; H01L 33/0095; C30B 29/38

(57) ABSTRACT

It is provided a seed crystal layer, composed of a group 13 nitride crystal selected from gallium nitride, aluminum nitride, indium nitride or the mixed crystals thereof, on an alumina layer on a single crystal substrate. By annealing under reducing atmosphere at a temperature of 950° C. or higher and 1200° C. or lower, convex-concave morphology is formed on a surface of the seed crystal layer so as to have an RMS value of 180 nm to 700 nm measured by an atomic force microscope. On the surface of the seed crystal layer, it is grown a group 13 nitride crystal layer composed of a group 13 nitride crystal selected from gallium nitride, aluminum nitride, indium nitride or the mixed crystals thereof.

### CROSS-REFERENCE TO RELATED APPLICATIONS

This is a continuation of PCT/JP2020/027802, filed Jul. 17, 2020, which claims priority to Japanese Application No. JP2019-165026 filed on Sep. 11, 2019, the entire contents of which are hereby incorporated by reference.

### TECHNICAL FIELD

The invention relates to a method of producing a group 13 nitride crystal layer and seed crystal substrate.

### BACKGROUND ARTS

There have been known light emitting devices such as light emitting diodes (LEDs) that use sapphire (α-alumina single crystal) as a monocrystalline substrate, with various types of gallium nitride (GaN) layers formed thereon. For example, a light emitting device have been mass-produced having the structures in which an n-type GaN layer, a multiple quantum well (MQW) layer with an InGaN quantum well layer and a GaN barrier layer grown alternately therein, and a p-type GaN layer are formed in a grown manner in this order on a sapphire substrate.

According to patent document 1 (Japanese Patent No. 6059061 B), it is described that a convex-concave surface is formed through hydrogen annealing treatment on a surface of an underlying substrate composed of a group 13 nitride crystal, followed by the growth of a group 13 nitride crystal layer.

According to patent document 2 (Japanese Patent No. 6126887 B), it is described that a convex-concave surface is formed by subjecting a surface of an underlying substrate composed of a group 13 nitride crystal layer to chlorine plasma etching, followed by the growth of a group 13 nitride crystal layer.

According to Patent document 3 (Japanese Patent No. 5667574 B), it is described that micro steps each having a specific dimension is formed on a surface of an underlying substrate composed of a group 13 nitride crystal layer, followed by the growth of a group 13 nitride crystal layer. The method of forming the micro steps includes dry etching, sand blasting, laser treatment and dicing.

Further, Patent document 4 discloses a gallium nitride crystal layer having a specific microstructure and free-standing substrate.
(Patent document 1) Japanese Patent No. 6059061 B
(Patent document 2) Japanese Patent No. 6126887 B
(Patent document 3) Japanese Patent No. 5667574 B
(Patent document 4) WO 2019/039207 A1

### SUMMARY OF THE INVENTION

However, in the case that a concave-convex surface is formed by treating an underlying substrate according to these prior arts and that a group 13 nitride crystal layer is grown thereon, the dislocation density of the surface of the group 13 nitride crystal layer is effectively reduced. However, due to the recent technical progress, it is further demanded the improvement of the light-emitting intensity. It is thus demanded to further reduce the dislocation density on the surface of the group 13 nitride crystal layer.

An object of the present invention is, in producing a layer of a group 13 nitride crystal selected from gallium nitride, aluminum nitride, indium nitride or the mixed crystals thereof on a seed crystal substrate, to further reduce the dislocation density of the layer of the group 13 nitride crystal layer.

A first aspect of the present invention is to provide a method of producing a group 13 nitride crystal layer, the method comprising:
a seed crystal layer growing step of providing a seed crystal layer comprising a group 13 nitride crystal selected from gallium nitride, aluminum nitride, indium nitride or the mixed crystals thereof, on an alumina layer on a single crystal substrate;
an annealing step of annealing said seed crystal layer under a reducing atmosphere at a temperature of 950° C. or higher and 1200° C. or lower to form convex-concave morphology on a surface of said seed crystal layer having an RMS value of 180 nm to 700 nm measured by an atomic force microscope; and
a step of growing a group 13 nitride crystal layer comprising a group 13 nitride crystal selected from gallium nitride, aluminum nitride, indium nitride or the mixed crystals thereof, on the surface of the seed crystal layer.

Further, the first aspect of the present invention provides a method of producing a seed crystal substrate, said method comprising:
a seed crystal layer growing step of providing a seed crystal layer comprising a group 13 nitride crystal selected from gallium nitride, aluminum nitride, indium nitride or the mixed crystals thereof, on an alumina layer; and
an annealing step of annealing the seed crystal layer under a reducing atmosphere at a temperature of 950° C. or higher and 1200° C. or lower to form a convex-concave morphology on a surface of the seed crystal layer having an RMS value of 180 nm to 700 nm measured by an atomic force microscope.

Further, a second aspect of the present invention provides a method of producing a group 13 nitride crystal layer, said method comprising:
a seed crystal layer growing step of providing a seed crystal layer comprising a group 13 nitride crystal selected from gallium nitride, aluminum nitride, indium nitride or the mixed crystals thereof, on an alumina layer on a single crystal substrate;
an etching step of etching a surface of the seed crystal layer by chlorine plasma etching to form recesses on the surface so that a ratio of C-plane is 10% or larger and 60% or smaller while the surface of the seed crystal layer is etched without a bias voltage applied on the seed crystal layer; and
a step of growing a group 13 nitride crystal layer comprising a group 13 nitride crystal selected from gallium nitride, aluminum nitride, indium nitride or the mixed crystals thereof, on the surface of the seed crystal layer.

Further, the second aspect of the present invention provides a method of producing a seed crystal substrate, said method comprising:
a seed crystal layer growing step of providing a seed crystal layer comprising a group 13 nitride crystal selected from gallium nitride, aluminum nitride, indium nitride or the mixed crystals thereof, on an alumina layer on a single crystal substrate; and
an etching step of etching a surface of the seed crystal layer by chlorine plasma etching to form recesses on said surface so that a ratio of C-plane is 10% or larger and 60% or smaller while the surface of the seed crystal layer is etched without a bias voltage applied on the seed crystal layer.

Further, a third aspect of the present invention provides a seed crystal substrate comprising:
a single crystal substrate;
an alumina layer on said single crystal substrate; and
a seed crystal layer provided on said alumina layer and comprising a group 13 nitride crystal selected from gallium nitride, aluminum nitride, indium nitride or the mixed crystals thereof,
wherein a surface of the seed crystal layer comprises a plurality of steps,
wherein heights of the steps are 0.2 to 2p m, and
wherein terrace widths of the steps are 0.25 to 2.0 mm.

Further, the third aspect of the present invention provides a group 13 nitride crystal layer, said method comprising the step of:
growing a group 13 nitride crystal layer comprising a group 13 nitride crystal selected from gallium nitride, aluminum nitride, indium nitride or the mixed crystals thereof, on the surface of the seed crystal layer of the seed crystal substrate described above.

According to the present invention, after an alumina layer is grown on a single crystal substrate, a seed crystal layer composed of a group 13 nitride crystal is film-formed on the alumina layer. Thereafter, the seed crystal layer is subjected to a specific surface treatment, or steps having specific dimensions are formed on the surface of the seed crystal layer so that it is possible to reduce the dislocation density on the surface of the group 13 nitride crystal layer thereon.

### BRIEF DESCRIPTION OF THE DRAWINGS

FIG. 1(a) shows the state that an alumina layer 2, seed crystal layer 3 and group 13 nitride crystal layer 13 are provided on a single crystal substrate 1, and FIG. 1(b) shows the group 13 nitride crystal layer 13 separated from the single crystal substrate.

FIG. 2(a) is a diagram schematically showing grain boundaries in the seed crystal layer, FIG. 2(b) is a cross sectional view schematically showing the state of the seed crystal layer 3 after the surface treatment, and FIG. 2(c) shows the state that the group 13 nitride crystal layer 13 is provided on the seed crystal layer 3.

FIG. 3(a) is a perspective view showing steps 19 (whose edges are in parallel with a-plane) on the surface of the seed crystal layer 3, and FIG. 3(b) is a plan view of FIG. 3(a).

FIG. 4(a) shows the mechanism of reducing dislocations by the steps, and FIG. 4(b) is a plan view showing steps 19 (whose edges are in parallel with m-plane) on the surface of the seed crystal layer 3.

FIG. 5(a) is a plan view showing the surface of the seed crystal layer having steps each having hexagonal pattern with the central part recessed, and FIG. 5(b) is an A-A cross sectional view of FIG. 5(a).

FIG. 6(a) is a plan view showing the surface of the seed crystal layer including steps each having triangle pattern with the central part recessed, and FIG. 6(b) is a B-B cross sectional view of FIG. 6(a).

FIG. 7(a) is a plan view showing the surface of the seed crystal layer including steps each having hexagonal pattern with the central part protruded, and FIG. 7(b) is a C-C cross sectional view of FIG. 7(a).

FIG. 8 is a diagram schematically illustrating cathode luminescence image of an upper surface 13a of a group 13 nitride crystal layer 13.

FIG. 9 is a photograph taken by a scanning type electron microscope of a cross section perpendicular to the upper surface 13a of the group 13 nitride crystal layer 13.

FIG. 10 is a diagram schematically showing a functional device 21 of the present invention.

### MODES FOR CARRYING OUT THE INVENTION

The present invention will be described further in detail, appropriately referring to drawings below.

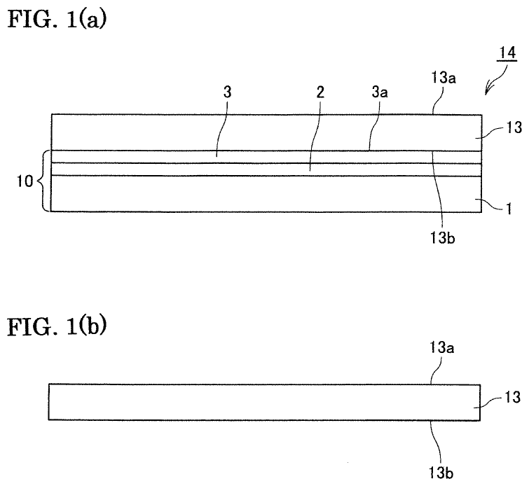

FIG. 1(a) shows a composite substrate 14 having an alumina layer 2, seed crystal layer 3 and group 13 nitride crystal layer 13 provided on a single crystal substrate 1, and FIG. 1(b) shows the group 13 nitride crystal layer 13 separated from the single crystal substrate.

(Single Crystal Substrate)

Although the material forming the single crystal substrate 1 is not limited, it includes sapphire, AlN template, GaN template, free-standing GaN substrate, SiC single crystal, MgO single crystal, spinel (MgAl₂O₄), LiAlO₂, LiGaO₂, and perovskite composite oxide such as LaAlO₃, LaGaO₃ or NdGaO₃ and SCAM (ScAlMgO₄). A cubic perovskite composite oxide represented by the composition formula [A_{1-y} (Sr₁₋ₓBaₓ)_{y}] [(Al_{1-z}Ga_{z})₁₋ᵤDu] O₃ (wherein A is a rare earth element; D is one or more element selected from the group consisting of niobium and tantalum; y=0.3 to 0.98; x=0 to 1; z=0 to 1; u=0.15 to 0.49; and x+z=0.1 to 2) is also applicable.

(Alumina Layer)

An alumina layer 2 may be then formed on the single crystal substrate 1 to obtain an underlying substrate.

The method of forming the alumina layer 2 may be a known technique, and may be sputtering, MBE (molecular beam epitaxy) method, vapor deposition, mist CVD method, sol gel method, aero sol deposition (AD) method, or the method of adhering an alumina sheet produced by tape molding or the like on the single crystal substrate, and sputtering is particularly preferred. Optionally, after the alumina layer is formed, it may be used after the thermal treatment, plasma treatment or ion beam irradiation. Although the method of thermal treatment is not particularly limited, the thermal treatment may be performed in air atmosphere, vacuum, a reducing atmosphere such as hydrogen or the like, or an inert atmosphere such as nitrogen or Ar, or the thermal treatment may be performed under pressure by means of a hot pressing (HP) furnace, hot isostatic pressing (HIP) furnace or the like.

Further, the sapphire substrate may be subjected to surface treatment to generate the alumina layer, and the seed crystal layer composed of the group 13 nitride may be formed on the alumina layer.

(Seed Crystal Layer)

Then, as shown in FIG. 1(a), the seed crystal layer 3 is provided on the alumina layer 2 produced as described above. The seed crystal layer 3 is subjected to surface treatment to obtain the seed crystal substrate 10.

The material forming the seed crystal layer 3 is made a nitride of one or two or more group 13 element(s) defined by IUPAC. The group 13 nitride is preferably gallium, aluminum or indium. Further, specifically, the crystal of the group 13 nitride is preferably GaN, AlN, InN, GaₓAl₁₋ₓN (1>x>0), GaₓIn₁₋ₓN (1>x>0), GaₓAl_{y}InN_{1-x-y} (1>x>0, 1>y>0).

Although the method of producing the seed crystal layer 3 is not particularly limited, it is preferably listed a gas phase method such as MOCVD (metal-organic chemical vapor deposition method), MBE (molecular beam epitaxy method), HVPE (hydride vapor phase epitaxy method), sputtering and the like, a liquid phase method such as sodium flux method, ammono-thermal method, hydrothermal method, sol-gel method and the like, a powder method utilizing the solid phase growth of powder and the combinations thereof.

For example, the formation of the seed crystal layer by MOCVD method may preferably be performed by depositing a low temperature-grown buffer GaN layer at 450 to 550° C. in 20 to 50 nm and then laminating a GaN film at 1000 to 1200° C. in a thickness of 2 to 4p m. Further, in the case that a thick seed crystal layer is necessary, for example, it is preferred to perform HVPE method by depositing a low temperature-grown buffer GaN layer at 450 to 550° C. in 20 to 50 nm and by then laminating a GaN film at 1000 to 1200° C. in a thickness of 4 to 500p m.

(Surface Treatment and Surface Morphology of Seed Crystal Layer)

The surface treatment of the seed crystal layer is performed according to either of the first, second and third aspects of the present invention.

(Surface Treatment According to the First Aspect)

According to the first aspect, the seed crystal layer is annealed under reducing atmosphere at a temperature of 950° C. or higher and 1200° C. or lower to form convex-concave morphology on the surface 3a of the seed crystal layer 3 so that the RMS value measured by an atomic force microscope is 180 to 700 nm, to obtain the composite substrate 14.

As the reducing atmospheric gas, it is preferred to apply that containing hydrogen gas as the main component. For example, it is preferred to apply gas mixture containing 50% or higher of hydrogen gas in volume and an inert gas (for example nitrogen gas) as the remainder. Further, it may be applied ammonia gas, or these gases may be mixed and applied. Further, the annealing temperature may preferably be made 950° C. to 1200° C. Further, the annealing time may be appropriately selected and may preferably be 5 to 60 minutes according to an example.

After such annealing, the surface of the seed crystal layer flat at atomic level is changed to convex-concave surface. Further, the convex-concave surface may have regularly or periodically formed convexes and concaves, or may have the irregular structure including large and small protrusions randomly distributed. Further, the convex-concave surface may preferably have a root mean square roughness RMS of 180 nm to 700 nm. Further, the root mean average roughness RMS of the convex-concave surface is evaluated by measuring a region of 25 μm by 25 μm by means of an atomic force electron microscope (AFM) and by analyzing the measurement results.

Further, in the case that the annealing temperature is lower than 950° C., the effect of reducing the dislocation density is not sufficiently obtained. It is considered that the convex-concave structure is not sufficiently obtained by the annealing under such condition. Further, in the case that the temperature is higher than 1200° C., sites of abnormal growth are generated. It is considered that large convexes and concaves are formed for preventing the formation of the group 13 nitride crystal layer.

(Surface Treatment According to Second Aspect)

According to the second aspect, the surface 3a of the seed crystal layer 3 is subjected to chlorine plasma etching to form concaves on the surface so that the ratio of C-plane is 10% or higher and 60% or lower, while the surface of the seed crystal layer is etched without a bias voltage applied on the seed crystal layer.

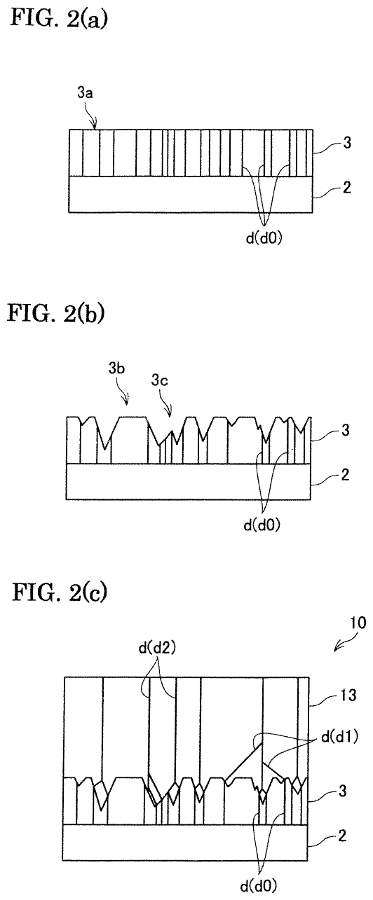

That is, dislocations d(d0) are present in the thickness direction inside of the seed crystal layer 3, as schematically shown in FIG. 2(a). The seed crystal layer is subjected to chlorine plasma etching. Chlorine gas is made plasma state by ICP (Inductively Coupled Plasma) to etch the surface of the seed crystal layer. As shown in FIG. 2(b), recesses 3c are formed on the surface of the seed crystal layer 3 and flat surface 3b remains between the recesses 3c. In the case of the etching by general ICP plasma, a bias voltage is applied on an object to be processed. According to the present aspect, a bias voltage is not applied on the seed crystal layer. This is to suppress the collision of ions (Cl ions) in the plasma onto the object to be processed occurring predominantly in the case that the bias voltage is applied, so that the etching is progressed mainly through the chemical reaction of the chlorine radicals and seed crystal. As shown n in FIG. 2(c), the dislocations d0 are propagated in the group 13 nitride crystal layer as d1 and d2 to reduce through dislocations d.

Recesses are formed on the surface of the seed crystal layer so that the ratio of the C-plane is made 10% or higher and 60% or lower. On the viewpoint of reducing the dislocation density, the ratio of the C-plane may more preferably be made 10% or higher and more preferably be made 40% or lower.

The actual calculation of the ratio p of the C-plane can be performed by measuring the surface 3a after the etching by means of a laser microscope or AFM (atomic force microscope) two-dimensionally and by applying known image-processing technique on the thus obtained measurement results (surface convex-concave data).

For making the ratio p of the C-plane 10% or higher and 60% or lower, it is preferred to make the gas flow rate of Cl₂ gas supplied into a chamber 20 sccm to 80 sccm, the gas pressure in the chamber 0.8 Pa to 3 Pa and the ICP electric power 200 W to 1000 W, and to adjust the etching time in a range of 100 minutes or longer and 280 minutes or shorter.

(Surface Treatment According to Third Aspect)

According to the third aspect, the surface 3a of the seed crystal layer 3 includes a plurality of steps, the height of the step is 0.2 to 2p m, and terrace width of the step is 0.25 to 2.0 mm. It is thereby possible to reduce the dislocation density of the group 13 nitride crystal layer 13 formed thereon by a fewer number of steps.

The height of the step is made 0.2 to 2 μm. In the case that the height of the step is lower than 0.2 μm, intergranular boundaries are not generated during the growth of the group 13 nitride crystal, and the mechanism of the reduction of the dislocations may not sufficiently be obtained, which is not preferred. In the case that the height of the step exceeds 2p m, the amount of inclusions generated in the intergranular boundaries or the vicinity is increased, which is not preferred.

Although the edges of the steps may be substantially parallel with a-plane or may be substantially parallel with m-plane of the group 13 nitride crystal or may be directed to any of the other directions, the edge may preferably be formed substantially in parallel with the a-plane of the group 13 nitride crystal. In the case that the edge of the step is formed in parallel with the a-plane, as the intergranular boundaries are extended at an angle nearer to the c-plane compared with the case that the edge is formed in parallel with the m-plane, a wider area is covered with the intergranular boundaries at the same growth thickness, providing preferred embodiment. Further, “parallel with the a-plane” includes the case that it is parallel with the a-plane and the case that it is substantially parallel with the a-plane (for example, the direction deviated in an angle smaller than 5° with respect to the a-plane).

The respective steps may be formed by dry etching, sand blasting, laser, dicing or the like, for example.

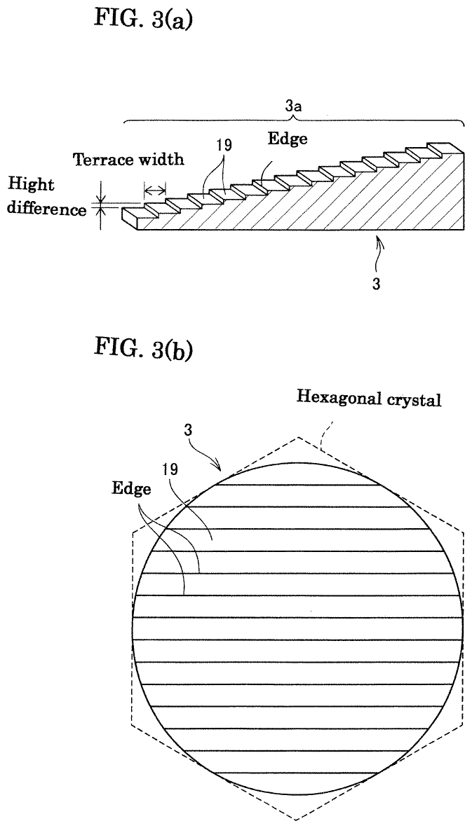

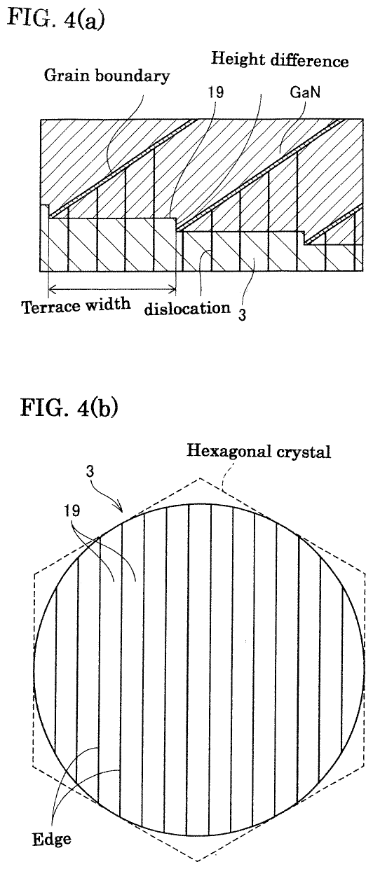

For example, according to an example shown in FIGS. 3(a) and 3(b), many steps 19 are regularly formed on the surface 3a of the seed crystal layer 3, and the edges of the respective steps 19 are substantially parallel with the a-plane of the group 13 nitride crystal. The width and height of the step satisfy the conditions as described above. As shown in FIG. 4(a), the dislocations tend to be absorbed at the intergranular boundaries by the effect of the steps.

According to an example shown in FIG. 4(b), the steps 19 are regularly formed on the surface of the seed crystal layer 3, and the edges of the respective steps are parallel with the m-plane of the tetragonal crystal of the group 13 nitride crystal layer.

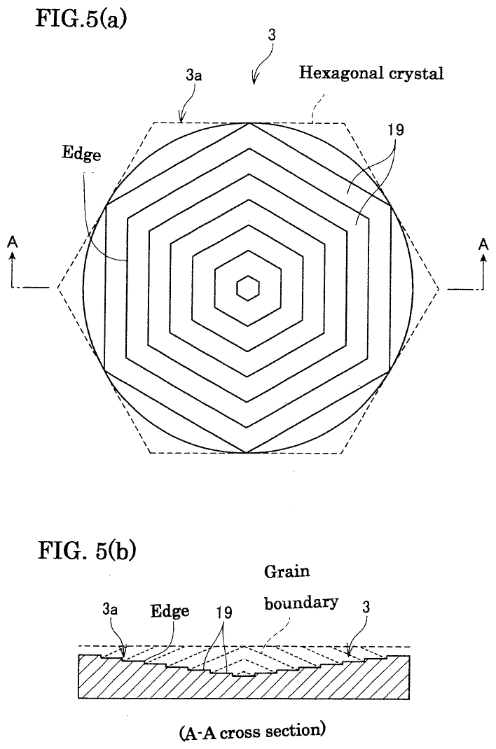

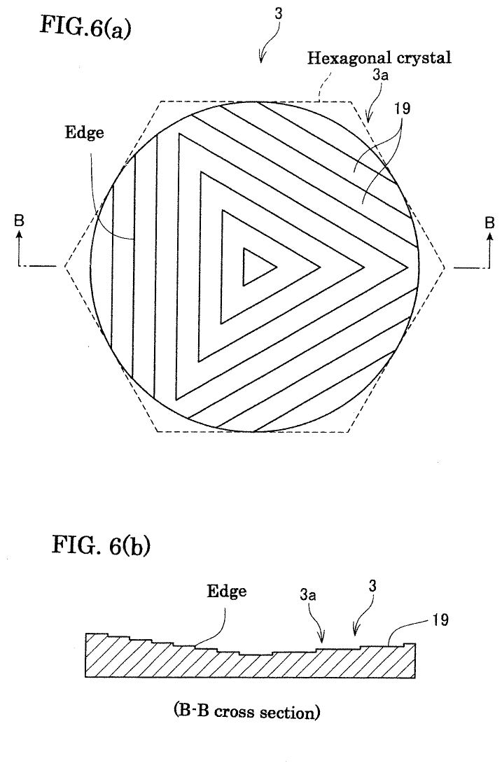

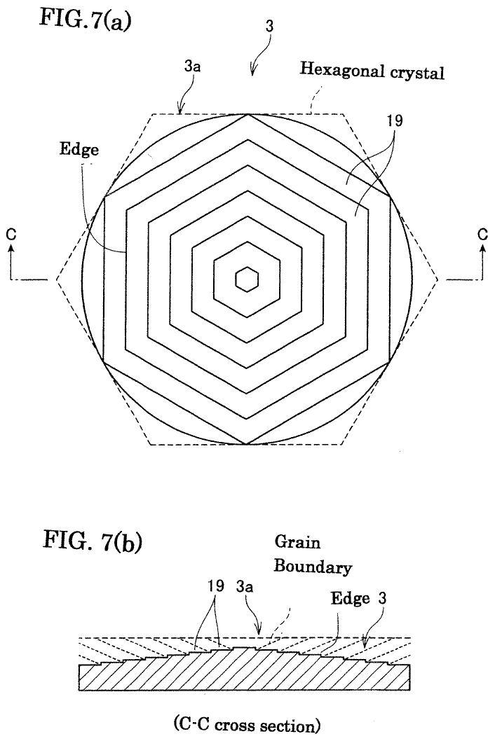

Further, the step may be formed in the pattern, in which the step has the shape whose center is recessed (center-recessed shape) in a longitudinal cross section of the seed crystal substrate and the shape of a point-symmetric figure viewed from the surface of the seed crystal layer. The point symmetric figure may be a triangle, rectangle, pentagon, hexagon or the like. According to examples shown in FIGS. 5(a) and 5(b), the edges of all the steps 19 are patterned to be hexagons parallel with the a-plane. According to examples shown in FIGS. 6(a) and 6(b), the edges of all the steps 19 are patterned to be a rectangular shape parallel with the a-plane. Further, according to examples of FIGS. 7(a) and 7(b), the center of the surface of the seed crystal layer is shaped to form a protrusion.

(Group 13 Nitride Crystal Layer)

According to the present invention, the group 13 nitride crystal layer is grown on the seed crystal layer.

The group 13 nitride crystal layer of the present invention is composed of a group 13 nitride crystal selected from gallium nitride, aluminum nitride, indium nitride or the mixed crystals thereof, and has an upper surface and bottom surface. For example, as shown in FIG. 1(b), the upper surface 13a and bottom surface 13b are opposed to each other in the group 13 nitride crystal layer 13.

The nitride forming the layer of the group 13 nitride crystal is gallium nitride, aluminum nitride, indium nitride or the mixed crystals thereof. Specifically, it may be GaN, AlN, InN, GaₓAl₁₋ₓN (1>x>0), GaₓIn₁₋ₓN (1>x>0), or GaₓAl_{y}In_{z}N (1>x>0, 1>y>0, x+y+z=1).

More preferably, the nitride forming the layer of the group 13 nitride crystal is a gallium nitride-based nitride. Specifically, it is GaN, GaₓAl₁₋ₓN (1>x>0.5), GaₓIn₁₋ₓN (1>x>0.4), or GaₓAl_{y}In_{z}N (1>x>0.5, 1>y>0.3, x+y+z=1).

The group 13 nitride may be further doped with a n-type dopant or p-type dopant in addition to zinc and calcium. In this case, a polycrystalline group 13 nitride may be used as a member or a layer other than a base material, such as a p-type electrode, or an n-type electrode, a p-type layer, or an n-type layer. A preferable example of the p-type dopant may be one type or more selected from the group consisting of beryllium (Be), magnesium (Mg), strontium (Sr) and cadmium (Cd). A preferable example of the n-type dopant may be one type or more selected from the group consisting of silicon (Si), germanium (Ge), tin (Sn), and oxygen (O).

According to a preferred embodiment, in the case that the upper surface of the group 13 nitride crystal layer is observed by cathode luminescence, it includes a linear high-luminance light-emitting part and a low-luminance light-emitting region adjacent to the high-luminance light-emitting part, and the high-luminance light-emitting part includes a part extending along the m-plane of the group 13 nitride crystal. Since the linear high-luminance light-emitting part appears on the upper surface, it is meant that the thick and linear high-luminance light-emitting part is generated by dopant components, minute components or the like contained in the group 13 nitride crystal. At the same time, the linear high-luminance light-emitting part is extended along the m-plane, meaning that the dopants are concentrated along the m-plane during the crystal growth and thick and linear high-luminance light-emitting part appears along the m-plane.

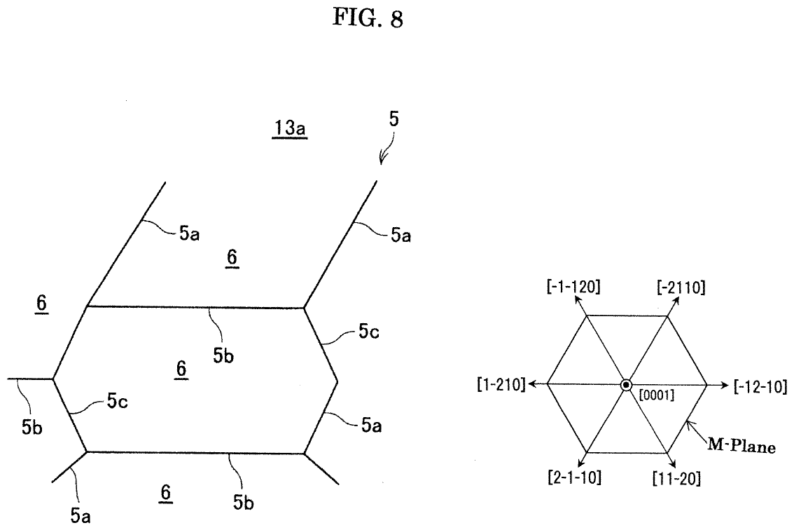

That is, in the case that the upper surface 13a of the group 13 nitride crystal layer is observed by cathode luminescence (CL), as schematically shown in FIG. 8, it is included the linear high-luminance light-emitting part 5 and low-luminance light-emitting region 6 adjacent to the high-luminance light-emitting part 5.

Further, the observation by CL is to be performed as follows.

The CL observation is performed by means of a scanning type electron microscope (SEM) equipped with a CL detector. For example, in the case that “S-3400N” scanning type electron microscope supplied by HITACHI Hi-Technologies equipped with Mini CL system supplied by Gatan, the measurement is preferably performed under the conditions of an acceleration voltage of 10 kV, probe current of “90”, working distance (W. D.) of 22.5 mm and magnification of 50 folds while the CL detector is inserted between a sample and object lens.

Further, the high-luminance light-emitting part and low-luminance light emitting region are distinguished as follows, based on the observation by cathode luminescence.

As to brightness of an image observed by CL under the conditions of an acceleration voltage of 10 kV, probe current “90”, a working distance (W. D.) of 22.5 mm and a magnitude of 50 folds, it is used an image processing software (for example, “WinRoof Ver 6.1.3” supplied by Mitani corporation) to prepare a histogram of gray scale of 256 grades whose vertical axis shows a degree and horizontal axis shows brightness (GRAY). Two peaks are confirmed in the histogram. The brightness at which the degree takes its minimum value between the two peaks is defined as a boundary, and the higher side is defined as the high-luminance light emitting part and the lower side is defined as the low-luminance light-emitting region.

Further, on the upper surface of the layer of the group 13 nitride crystal, the linear high-luminance light emitting part and low-luminance light-emitting region are adjacent to each other. The adjacent low-luminance light-emitting regions are distinguished by the linear high-luminance light-emitting part between them. Here, the linearity of the high-luminance light-emitting part means that the high-luminance light-emitting part is elongated lengthwise between the adjacent low-luminance light-emitting regions to provide a boundary line.

Here, the line of the high-luminance light emitting part may be a straight line, curved line or a combination of the straight line and curved line. The curved line includes various shapes such as circle, ellipse, parabola and hyperbola. Further, the high-luminance light emitting parts extending in different directions may be continuous with each other, and an end of the high-luminance light-emitting part may be discontinued.

On the upper surface of the layer of the crystal of the group 13 nitride, the low-luminance light-emitting region may be an exposed surface of the crystal of the group 13 nitride grown thereunder and is extended two-dimensionally and in a planar shape. On the other hand, the high-luminance light-emitting part is of a linear shape and extended one-dimensionally to provide the boundary line dividing the adjacent low-luminance light-emitting regions. For example, it is considered that dopant components, minute components and the like are discharged from the crystal of the group 13 nitride grown from the bottom and concentrated between the group 13 nitride crystals adjacent with each other during the growth, thereby generating linear and strongly light-emitting part between the adjacent low-luminance light-emitting regions on the upper surface.

As such, the shape of the low-luminance light-emitting region is not particularly limited, and usually elongated planarly and two-dimensionally. On the other hand, it is necessary that the line of the high-luminance light-emitting part is of an elongate shape. On the viewpoint, the width of the high-luminance light-emitting part may preferably be 100 μm or smaller, more preferably be 20 μm or smaller and particularly preferably be 5 μm or smaller. Further, the width of the high-luminance light-emitting part is usually 0.01 μm or larger.

Further, the ratio (length/width) of the length and width of the high-luminance light-emitting part may preferably be 1 or more and more preferably be 10 or more.

Further, on the viewpoint of the present invention, on the upper surface, the ratio of the area of the high-luminance light-emitting parts with respect to the area of the low-luminance light-emitting regions (area of high-luminance light-emitting parts/area of low-luminance light-emitting regions) may preferably be 0.001 or more and more preferably be 0.01 or more.

Further, on the viewpoint of the present invention, on the upper surface, the ratio of the area of the high-luminance light-emitting parts with respect to the area of the low-luminance light-emitting regions (area of high-luminance light-emitting parts/area of low-luminance light-emitting regions) may preferably be 0.3 or less and more preferably be 0.1 or less.

According to a preferred embodiment, the high-luminance light-emitting part includes a portion extending along the m-plane of the crystal of the nitride of the group 13 element. For example, according to the example shown in FIG. 8, the high-luminance light-emitting part 5 is elongated in an elongate shape and includes portions 5a, 5b and 5c elongating along the m-plane. The directions along the m-plane of the hexagonal crystal of the nitride of the group 13 element is, specifically, [−2110], [−12−10], [11−20], [2−1−10], [1−210] or [−1−120] direction, and the high-luminance light-emitting part 5 includes a part of a side of a substantially hexagonal shape reflecting the hexagonal crystal. Further, the linear high-luminance light-emitting part is elongated along the m-plane, meaning that the lengthwise direction of the high-luminance light-emitting part is elongated in the direction of each of [−2110], [−12−10], [11−20], [2−1−10], [1−210] and [−1−120]. Specifically, it is permitted that the lengthwise direction of the linear high-luminance light-emitting part is inclined preferably in a range of ±1° and more preferably in a range of ±0.3° with respect to the m-plane.

According to a preferred embodiment, on the upper surface, the linear high-luminance light-emitting part is elongated approximately along the m-plane of the crystal of the nitride of the group 13 element. It means that a main portion of the high-luminance light-emitting part is elongated along the m-plane and preferably the continuous phase of the high-luminance light-emitting part is elongated approximately along the m-plane. In this case, the portion extending in the direction along the m-plane may preferably occupy 60 percent or more, more preferably 80 percent or more and may occupy substantially the whole of the whole length of the high-luminance light-emitting part.

According to a preferred embodiment, on the upper surface of the layer of the crystal of the group 13 nitride, the high-luminance light-emitting part constitutes continuous phase and the low-luminance light-emitting region constitutes discontinuous phases divided by the high-luminance light-emitting part. For example, as shown in the schematic view of FIG. 8, the linear high-luminance light-emitting part 5 form the continuous phase and the low-luminance light-emitting regions 6 form the discontinuous phases divided by the high-luminance light-emitting part 5.

Here, although the continuous phase means that the high-luminance light-emitting part 5 is continuous on the upper surface, it does not necessarily mean that all the high-luminance light emitting parts 5 are completely continuous, and it is permitted that a small part of the high-luminance light-emitting part 5 is separated from the other high-luminance light-emitting part 5 as far as it does not affect the whole pattern.

Further, the dispersed phase means that the low-luminance light-emitting regions 6 are approximately divided by the high-luminance light-emitting part 5 into many regions which are not continuous. Further, in the case that the low-luminance light-emitting regions 6 are divided by the high-luminance light-emitting part 5 on the upper surface, it is permitted that the low-luminance light-emitting regions 6 are continuous inside of the layer of the crystal of the group 13 nitride.

According to a preferred embodiment, the half value width of the reflection at (0002) plane of X-ray rocking curve on the upper surface of the layer of the group 13 nitride crystal is 3000 seconds or less and 20 seconds or more. It indicates that the surface tilt angle is low and the crystal orientations are highly oriented, as a whole, as a single crystal, on the upper surface. As the microstructure has the cathode luminescence distribution as described above and the crystal orientations at the surface are highly orientated as a whole as such, it is possible to reduce the distribution of property on the upper surface of the layer of the crystal of the group 13 nitride, to obtain uniform properties of various kinds of functional devices provided thereon and to improve the yields of the functional devices.

On the viewpoint, the half value width of the reflection at (0002) plane of X-ray rocking curve on the upper surface of the layer of the group 13 nitride crystal may preferably be 1000 seconds or less and 20 second or more, and more preferably be 500 seconds or less and 20 seconds or more. Here, it is actually difficult to make the half value width of the reflection at (0002) plane of X-ray rocking curve on the upper surface of the layer of the group 13 nitride crystal lower than 20 seconds.

Further, the reflection at (0002) plane of the X-ray rocking curve is measured as follows. It is used an XRD system (for example, D8-DISCOVER supplied by Bruker-AXS) to perform the measurement under conditions of a tube voltage of 40 kV, a tube current of 40 mA, a collimator size of 0.1 mm, an anti-scattering slit of 3 mm, a range of ω=angle of peak position of ±0.3°, an ω step width of 0.003° and a counting time of 1 second. According to the measurement, it is preferred to use a Ge (022) non-symmetrical monochromator to convert CuKα ray to parallel and monochrome ray (half value width of 28 seconds) and to perform the measurement after standing the axis at a tilt angle CHI of about 0°. Then, the half value width of reflection at (0002) plane of X-ray rocking curve can be calculated by using an XRD analysis software (supplied by Bruker-AXS, LEPTOS4.03) and performing peak search. It is preferred to apply peak search condition of Noise filter “10”, Threshold “0.30” and Points “10”.

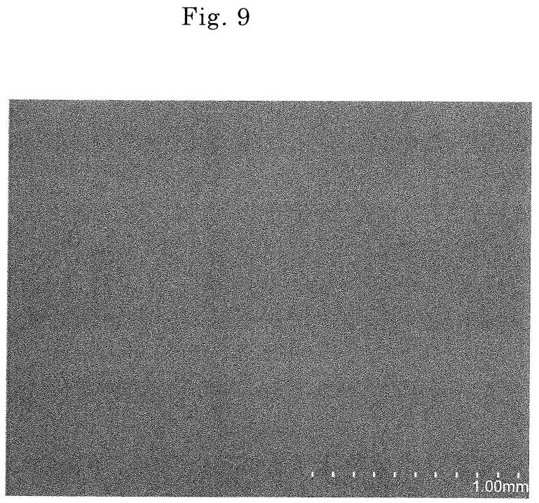

According to a preferred embodiment, voids are not observed on the cross section substantially perpendicular to the upper surface of the layer of the crystal of the group 13 nitride. That is, as shown in the SEM photograph of FIG. 9, voids (spaces) and crystal phases other than the crystal of the group 13 nitride are not observed. Here, the presence of the voids is observed as follows.

The voids are observable by observing the cross section substantially perpendicular to the upper surface of the layer of the crystal of the group 13 nitride by a scanning type electron microscope (SEM), and the void is defined as a space whose maximum width is 1 μm to 500 μm. It is used a scanning type electron microscope (“S-3400N” supplied by HITACHI Hi Technologies Co. Ltd.) for the SEM observation, for example. It is preferred to apply the measurement conditions of an acceleration voltage of 15 kV, a probe current “60”, a working distance (W. D.) of 6.5 mm and a magnification of 1700 folds.

Further, in the case that the cross section substantially perpendicular to the upper surface of the layer of the crystal of the group 13 nitride is observed by the scanning type electron microscope (under the measurement conditions as described above), it is not observed clear grain boundaries accompanied with structural macro defects such as voids. According to such microstructure, it is considered that the increase of resistance or deviation of a property due to the clear grain boundaries can be suppressed in the case that a functional device such as a light-emitting device is produced on the layer of the group 13 nitride crystal.

Further, according to a preferred embodiment, the dislocation density on the upper surface of the layer of the group 13 nitride crystal is 1×10²/cm² or more and 1×10⁶/cm² or less. It is particularly preferred to make the dislocation density 1×10⁶/cm² or less, on the viewpoint of improving the properties of the functional device. On the viewpoint, the dislocation density is more preferably 3×10³/cm² or less. The dislocation density is to be measured as follows.

It may be used a scanning type electron microscope (SEM) with a CL detector for the measurement of the dislocation density. For example, in the case that it is used a scanning type electron microscope (“S-3400N” supplied by HITACHI Hi Technologies Co. Ltd.) equipped with Mini CL system produced by Gatan for the CL observation, the dislocated positions are observed as dark spots without emitting light. The density of the dark spots is measured to calculate the dislocation density. It is preferably measured under the measurement conditions of an acceleration voltage of 10 kV, a probe current “90”, a working distance (W. D.) of 22.5 mm and a magnification of 1200 folds, while the CL detector is inserted between a sample and an object lens.

Further, according to a preferred embodiment, the half value widths of the reflection at the (0002) plane and of the reflection at the (1000) plane of the X-ray rocking curve on the upper surface of the group 13 nitride crystal layer are 3000 seconds or less and 20 seconds or more and 10000 seconds or less and 20 seconds or more, respectively. It means that both of the surface tilt angle and surface twist angle on the upper surface are low, and that the crystal orientations are highly orientated as a whole as a single crystal. As the microstructure has the crystal orientations at the surface highly orientated as a whole as such, it is possible to reduce the distribution of property on the upper surface of the layer of the group 13 nitride crystal, to obtain uniform properties of various functional devices provided thereon and to improve the yields of the functional devices.

Further, according to a preferred embodiment, the half value width of the reflection at (1000) plane of the X-ray rocking curve on the upper surface of the layer of the group 13 nitride crystal is 10000 seconds or less and 20 seconds or more. It indicates that the surface twist angle is very low on the upper surface and that the crystal orientations are highly orientated as a whole as a single crystal. As the microstructure has the cathode luminescence distribution as described above and the crystal orientations on the surface are highly orientated as a whole as such, it is possible to reduce the distribution of property at the upper surface of the layer of the group 13 nitride crystal, to obtain uniform properties of various functional devices provided thereon and to improve the yields of the functional devices.

On the viewpoint, the half value width of the reflection at (1000) plane of the X-ray rocking curve on the upper surface of the layer of the group 13 nitride crystal may preferably be 5000 seconds or less, more preferably be 1000 seconds or less and more preferably be 20 seconds or more. Further, it is actually difficult to make the half value width to a value lower than 20 seconds.

Further, the reflection at (1000) plane of the X-ray rocking curve is measured as follows. It is used an XRD system (for example, D8-DISCOVER supplied by Bruker-AXS) to perform the measurement under conditions of a tube voltage of 40 kV, a tube current of 40 mA, no collimator, an anti-scattering slit of 3 mm, a range of ω=angle of peak position of ±0.3°, an ω step width of 0.003° and a counting time of 4 seconds. According to the measurement, it is preferred to use a Ge (022) non-symmetrical reflection monochromator to convert CuKα ray to parallel and monochrome ray (half value width of 28 seconds) and to perform the measurement after standing the axis at a tilt angle CHI of about 88°. Then, the half value width of reflection at (1000) plane of X-ray rocking curve can be calculated by using an XRD analysis software (supplied by Bruker-AXS, LEPTOS4.03) and performing peak search. It is preferred to apply peak search condition of Noise Filter “10”, Threshold “0.30” and Points “10”.

The layer of the group 13 nitride crystal is formed so that the crystal orientations approximately conform to the crystal orientations of the seed crystal layer. The method of forming the layer 13 of the group 13 nitride crystal is not particularly limited as long as its crystalline orientation is substantially aligned with the crystal orientation of the seed crystal layer. It may be preferably listed vapor phase methods such as MOCVD, HVPE and the like, liquid phase methods such as Na flux method, ammonothermal method, hydrothermal method and sol-gel method, a powder method utilizing solid phase growth of powder, and the combinations thereof. It is particularly preferred to be performed by Na flux method.

In the case that the layer of the group 13 nitride crystal is formed by Na flux method, it is preferred to strongly agitate melt and to mix the melt uniformly and sufficiently. Although such agitation method includes swinging, rotation and vibration, the method is not limited.

The formation of the layer of the group 13 nitride crystal by Na flux method may preferably be performed by filling, in a crucible with the seed crystal substrate provided therein, melt composition containing a group 13 metal, Na metal and optionally a dopant (for example, an n-type dopant such as germanium (Ge), silicon (Si), oxygen or the like or a p-type dopant such as beryllium (Be), magnesium (Mg), calcium (Ca), strontium (Sr), zinc (Zn), cadmium (Cd) or the like, by elevating the temperature and pressure to 830 to 910° C. and 3.5 to 4.5 MPa under nitrogen atmosphere, and then by rotating the crucible while the temperature and pressure are held. The holding time may be made 10 to 100 hours, although it is different depending on the target film thickness.

Further, the thus obtained gallium nitride crystal produced by Na flux method may preferably be subjected to grinding by a grinder to make the surface flat, and the surface may preferably be flattened by lapping by diamond grinding stones.

(Method of Separating Layer of Crystal of Group 13 Nitride)

Then, the layer of the group 13 nitride crystal may be separated from the single crystal substrate to obtain a free-standing substrate including the layer of the group 13 nitride crystal.

Here, the method of separating the layer of the group 13 nitride crystal from the single crystal substrate is not limited. According to a preferred embodiment, the layer of the group 13 nitride crystal is spontaneously separated from the single crystal substrate, during a cooling step after growing the layer of the group 13 nitride crystal.

Alternatively, the layer of the group 13 nitride crystal may be separated from the single crystal substrate by chemical etching.

Etchants for performing the chemical etching may preferably be a strong acid such as sulfuric acid, chloric acid or the like, mixed solution of sulfuric acid and phosphoric acid, or a strong alkali such as sodium hydroxide aqueous solution, potassium hydroxide aqueous solution or the like. Further, the chemical etching may preferably be performed at a temperature of 70° C. or more.

Alternatively, the layer of the group 13 nitride crystal may be peeled off from the single crystal substrate by laser lift-off method.

Alternatively, the layer of the group 13 nitride crystal may be peeled off from the single crystal substrate by grinding.

Alternatively, the layer of the group 13 nitride crystal may be peeled off from the single crystal substrate with a wire saw.

(Free-Standing Substrate)

The layer of the group 13 nitride crystal may be separated from the single crystal substrate to obtain a free-standing substrate. The term “free-standing substrate” as used in the present invention means a substrate that is not deformed or broken under its own weight during handling and can be handled as a solid. The free-standing substrate of the present invention can be used not only as a substrate for various types of semiconductor devices such as light emitting devices, but also as a member or a layer other than the base material, such as an electrode (which may be a p-type electrode or an n-type electrode), a p-type layer, or an n-type layer. The free-standing substrate may include one or more of the other layers.

In the case that the layer of the group 13 nitride crystal forms the free-standing substrate, the free-standing substrate should have a thickness that allows for free-standing and preferably has a thickness of 20 μm or more, more preferably 100 μm or more, and further preferably 300 μm or more. No upper limit should be set on the thickness of the free-standing substrate, but it is realistic to have a thickness of 3000 μm or less in terms of manufacturing cost.

(Composite Substrate)

It can be used the single crystal substrate with the layer of the group 13 nitride crystal provided thereon as a template substrate for forming another functional layer thereon without separating the layer of the group 13 nitride crystal.

(Functional Device)

It is not particularly limited a functional device structure provided on the layer of the group 13 nitride crystal, it may have a function of light-emitting function, rectifying function or electric power-controlling function.

It is not limited the structure or production method of a light-emitting device using the layer of the group 13 nitride crystal of the present invention. Typically, the light-emitting device is produced by providing a light-emitting functional layer on the layer of the group 13 nitride crystal. Further, the layer of the group 13 nitride crystal may be used as an electrode (possible p-type electrode or n-type electrode), or a member or layer other than p-type layer or n-type layer or the like to produce the light-emitting device.

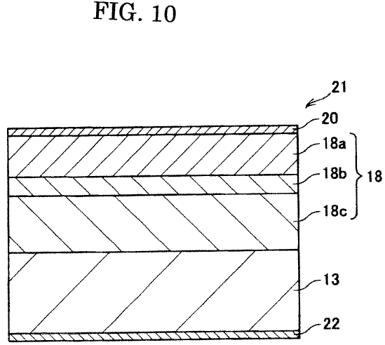

FIG. 10 schematically shows the construction of layers according to an embodiment of the present invention. The light-emitting device 21 shown in FIG. 10 includes a free-standing substrate 13 and a light emitting function layer 18 formed on the substrate. The light-emitting function layer 18 provides light-emission based on the principle of a light-emitting device such as LED or the like by appropriately providing an electrode or the like and applying a voltage.

The light emitting functional layer 18 is formed on the substrate 13. The light emitting functional layer 18 may be provided entirely or partially on the surface of the substrate 13 or may be provided entirely or partially on a buffer layer to be described hereinafter if the buffer layer is formed on the substrate 13. The light emitting functional layer 18 may take one of various known layer configurations that provide light emission based on the principle of light emitting devices as represented by LED's by appropriately providing electrodes and/or phosphors thereon and applying a voltage therebetween. Accordingly, the light emitting functional layer 18 may emit visible light of, for example, blue and red or may emit ultraviolet light without or with visible light. The light emitting functional layer 18 preferably forms at least a part of a light emitting device that exploits a p-n junction and the p-n junction may include an active layer 18b between a p-type layer 18a and an n-type layer 18c, as shown in FIG. 10. In this case, a double heterojunction or a single heterojunction (hereinafter referred to collectively as heterojunction) may be employed in which the active layer has a bandgap smaller than that of the p-type layer and/or the n-type layer. A quantum well structure in which the active layer is thinned may also be taken as one form of p-type layer/active layer/n-type layer. A double heterojunction in which the active layer has a bandgap smaller than those of the p-type layer and the n-type layer should obviously be employed to obtain a quantum well. Many quantum well structures may also be stacked to provide a multiple quantum well (MQW) structure. These structures allow to have a higher luminous efficiency compared to p-n junction. The light emitting functional layer 18 thus preferably includes the p-n junction, heterojunction and/or quantum well junction having a light emitting feature. Further, 20 and 22 represent examples of electrodes.

Accordingly, one or more layers forming the light emitting functional layer 18 can include at least one or more selected from the group consisting of the n-type layer with n-type dopants doped therein, the p-type layer with p-type dopants doped therein, and the active layer. In the n-type layer, the p-type layer, and the active layer (if exists), the main components may be of the same material or may be of respectively different materials.

The material of each layer forming the light emitting functional layer 18 is not particularly limited as long as grown in a manner generally following the crystal orientation of the layer of the group 13 nitride crystal and having light emitting function, but preferably includes one type or more selected from gallium nitride (GaN)-based material, zinc oxide (ZnO)-based material, and aluminum nitride (AlN)-based material as the main component and may appropriately contain dopants for controlling to be p-type or n-type. Gallium nitride (GaN)-based material is particularly preferable. The material of the light emitting functional layer 18 may be a mixed crystal with, for example, AlN, InN, etc. solid-solved in GaN to control the bandgap. As mentioned in the last paragraph, the light emitting functional layer 18 may employ the heterojunction composed of multiple types of material systems. For example, the p-type layer may employ the gallium nitride (GaN)-based material, while the n-type layer may employ the zinc oxide (ZnO)-based material. Alternatively, the p-type layer may employ the zinc oxide (ZnO)-based material, while the active layer and the n-type layer may employ the gallium nitride (GaN)-based material, the combination of materials being not particularly limited.

The film formation method for the light emitting functional layer 18 and the buffer layer is preferably exemplified by a gas phase method such as MOCVD, MBE, HYPE, and sputtering, a liquid phase method such as Na flux method, ammonothermal method, hydrothermal method, and sol-gel method, a powder method utilizing the solid phase growth of powder, and the combinations thereof, though not particularly limited as long as being grown in a manner generally following the crystal orientation of the layer of the group 13 nitride crystal.

### EXAMPLES

### Inventive Examples and Comparative Examples of First Aspect

### Comparative Example A1

### (Production of Gallium Nitride Free-Standing Substrate)

After an alumina layer 2 with a thickness of 0.3 μm was film-formed by sputtering on a sapphire substrate 1 with a diameter φ of 2 inches, a gallium nitride underlying layer wad film-formed at 500° C. by MOCVD method and a seed crystal layer 3 composed of gallium nitride of a thickness of 2 μm was then formed thereon to provide a seed crystal substrate 10.

The seed crystal layer was not particularly subjected to surface treatment. RMS (root mean roughness) of the seed crystal layer was proved to be 0.3 nm.

The seed crystal substrate was then placed in an alumina crucible in a glove box filled with nitrogen atmosphere. Then, gallium metal and sodium metal were filled in the crucible so that Ga/Ga+Na (mol %) was made 15 mol %, and the crucible was closed with an alumina plate. The crucible was contained in an inner container of stainless steel, which was then contained in an outer container of stainless steel capable of including it, and the outer container was then closed with a container lid equipped with a pipe for introducing nitrogen. The outer container was positioned on a rotatable table provided in a heating part of a crystal production system which was subjected to baking under vacuum in advance, and a pressure-resistant container was sealed with a lid. The inside space of the pressure-resistant container was then evacuated by a vacuum pump to a pressure of 0.1 Pa or less. While an upper heater, middle heater and lower heater were adjusted to heat the heated inside space to 870° C., nitrogen gas was introduced from a nitrogen gas bombe to 4.0 MPa, and the outer container was rotated around a central axis at a rate of 20 rpm clockwise and anti-clockwise at a predetermined interval. The acceleration time was made 12 seconds, holding time was made 600 seconds, deceleration time was made 12 seconds and stopping time was made 0.5 seconds. Such state was maintained for 40 hours. Thereafter, the temperature and pressure were lowered to room temperature and atmospheric pressure through natural cooling, the lid of the pressure-resistant container was opened and the crucible was taken out from the inside. Solidified sodium metal in the crucible was removed to obtain a composite substrate. It was grown gallium nitride single crystal having a thickness of 600 μm on the seed crystal layer.

Then, laser light was irradiated from the side of the sapphire substrate of the composite substrate so that the gallium crystal layer was separated from the sapphire substrate.

(Measurement of Dislocation Density)

It was then measured the dislocation density of the upper surface of the layer of the group 13 nitride crystal. The CL observation was performed to measure the density of dark spots at the dislocated positions so that the dislocation density was calculated. As a result of the observation of five visual fields each having sizes of 80 μm×105 μm, it was proved to be 3.4×10⁴/cm² in average.

### Inventive Examples A1 to A7 and Comparative Examples A2 to A7

The surface of the seed crystal substrate was subjected to the surface treatment as described below in the comparative example A1 and a gallium nitride layer was grown thereon.

Specifically, the surface of the seed crystal layer was subjected to annealing under atmosphere, temperature, time and pressure conditions described in table 1. Further, in comparative example A7, the surface of the seed crystal substrate was subjected to induction coupling plasma (ICP) etching in Cl₂ gas under a pressure of 1 Pa for 2 minutes.

Then, as to the surfaces of the seed crystal substrates after surface treatment in the respective examples, the root mean roughness RMS of the surface of the seed crystal layer after the surface treatment was measured by means of an atomic force microscope (AFM).

Then, the gallium nitride crystal layer was film-formed according to the same procedure as that of the comparative example A1. The thus obtained gallium nitride layer was subjected to cathode luminescence measurement at an acceleration voltage of 15 kV, and the dislocation density on the surface was obtained based on the thus obtained image.

Further, the presence or absence of abnormal growth of crystals of the respective gallium nitride layers was confirmed, by means of a polarizing microscope. The results were shown in table 1.

(Comparative Example A8)

The gallium nitride crystal layer was grown according to the same procedure as that of the inventive example A1, and the surface state was evaluated. However, according to the comparative example A8, the alumina layer was not provided on the sapphire substrate and the gallium nitride seed crystal layer was directly formed thereon. The test was performed as the inventive example A1 except the above condition.

TABLE 1

| | | | | | | Surface | | |
|---|---|---|---|---|---|---|---|---|
| | | | | | | roughness | Presence of | |
| | Processing of | | Temp- | | | of underlying | absence of | dislocation |
| | convex- | Atmosphereic | erature | Time | Pressure | substrate | abnormal | density |
| No. | concave | gas | [° C.] | [min] | [kPa] | RMS [nm] | growth | [/cm2] |
| Com. Ex. A1 | No processing (as-grown) | | | | | 0.3 | absent | 3.4E+04 |
| Com. Ex. A2 | Annealing | Hydrogen 100% | 1250 | 20 | 10 | 830 | present | 7.4E+02 |
| Inv. Ex. A1 | Annealing | Hydrogen 100% | 1200 | 20 | 10 | 680 | absent | 7.4E+02 |
| Inv. Ex. A2 | Annealing | Hydrogen 100% | 1100 | 20 | 10 | 440 | absent | 1.5E+03 |
| Inv. Ex. A3 | Annealing | Hydrogen 100% | 1000 | 20 | 10 | 270 | absent | 3.0E+03 |
| Inv. Ex. A4 | Annealing | Hydrogen 100% | 950 | 20 | 10 | 180 | absent | 4.5E+03 |
| Com. Ex. A3 | Annealing | Hydrogen 100% | 900 | 20 | 10 | 120 | absent | 2.5E+04 |
| Com. Ex. A4 | Annealing | Hydrogen 100% | 850 | 20 | 10 | 90 | absent | 2.8E+04 |
| Com. Ex. A5 | Annealing | Hydrogen 100% | 800 | 20 | 10 | 50 | absent | 2.9E+04 |
| Inv. Ex. A5 | Annealing | Hydrogen 100% | 1100 | 40 | 10 | 490 | absent | 2.2E+03 |
| Inv. Ex. A6 | Annealing | Hydrogen 100% | 1100 | 20 | 100 | 520 | absent | 1.5E+03 |
| Inv. Ex. A7 | Annealing | Hydrogen 90% + | 1100 | 20 | 10 | 430 | absent | 2.2E+03 |
| | | Nitrogen | | | | | | |
| Com. Ex. A6 | Annealing | Hydrogen 100% | 1100 | 20 | 10 | 15 | absent | 3.1E+04 |
| Com. Ex. A7 | C12 etching | — | — | — | — | 190 | present | 2.8E+04 |
| Com. Ex. A8 | Annealing | Hydrogen 100% | 1100 | 20 | 10 | 260 | absent | 7.5E+05 |

Alumina layer is not present in comparative example A8

As described above, as the surface treatment according to the first aspect of the present invention is combined with the seed crystal layer on the alumina layer and specific gallium nitride crystal layer, it was proved that particularly considerable advantageous effect can be obtained. That is, the state of the crystal growth was good and dislocation density was considerably reduced beyond expectation.

(Evaluation)

Then, the upper surfaces and bottom surfaces of the gallium nitride free-standing substrates of the respective inventive examples were subjected to polishing and subjected to the CL observation by means of a scanning type electron microscope (SEM) equipped with a CL detector. As a result, white-light emitting high-luminance light emitting parts were confirmed inside of gallium nitride crystal based on the CL photograph. Further, at the same time, as the visual field was confirmed by SEM observation, voids or the like were not confirmed and it was confirmed that uniform gallium nitride crystal was grown.

Further, the gallium nitride free-standing substrate was cut along a cross section perpendicular to the upper surface, and the cut surface was subjected to polishing and subjected to the CL observation by means of a scanning type electron microscope (SEM) equipped with a CL detector. As a result, white light-emitting high-luminance light-emitting parts were confirmed inside of gallium nitride crystal based on the CL image. However, at the same time, as the same visual field was observed by SEM, voids or the like were not confirmed and uniform gallium nitride crystal was proved to be grown. That is, further on the cross section of the gallium nitride layer, similar to the upper surface, although the high-luminance light-emitting parts were present based on the CL observation, it was not present the microstructure having the same or similar shape as the high-luminance light-emitting part observed by the CL photograph in the same visual field by means of the SEM.

(Film Formation of Light-Emitting Function Layer by MOCVD Method)

Applying MOCVD method, on the upper surface of the free-standing gallium nitride substrate of the inventive example A1, as a n-type layer, it was deposited an n-GaN layer in 1 μm at 1050° C. doped so that an atomic concentration of Si atoms became 5×10¹⁸/cm³. Then, as a light-emitting layer, it was deposited a multiple quantum well layers at 750° C. Specifically, five layers of well layers of 2.5 nm of InGaN and six layers of barrier layers of 10 nm of GaN were alternately deposited. Then, as a p-type layer, it was deposited p-type GaN in 200 nm at 950° C. doped so that an atomic concentration of Mg atoms became 1×10¹⁹/cm³. Thereafter, it was taken out of an MOCVD apparatus and then subjected to heat treatment at 800° C., in nitrogen atmosphere for 10 minutes as an activating treatment of Mg ions in the p-type layer.

(Production of Light-Emitting Device)

By photolithography process and vapor deposition method, on the surface on the opposite side of the n-GaN layer and p-GaN layer of the free-standing gallium nitride substrate, Ti film, Al film, Ni film and Au film were patterned in thicknesses of 15 nm, 70 nm, 12 nm and 60 nm, respectively as a cathode electrode. Thereafter, for improving ohm contact characteristic, heat treatment was performed at 700° C. for 30 seconds under nitrogen atmosphere. Further, by photolithography process and vapor deposition method, Ni film and Au film were patterned in thicknesses of 6 nm and 12 nm, respectively, as a transparent anode on the p-type layer. Thereafter, for improving the ohmic contact characteristic, heat treatment was performed at 500° C. for 30 seconds under nitrogen atmosphere. Further, by photolithography process and vapor deposition method, on a partial region of a top surface of the Ni and Al films as the transparent anode, Ni film and Au film were patterned in thicknesses of 5 nm and 60 nm, respectively, as a pad for the anode. The thus obtained substrate was cut into chips, which were mounted on lead frames to obtain light-emitting devices of vertical type structure.

(Evaluation of Light-Emitting Device)

Hundred samples were arbitrarily selected from the thus produced devices, and electricity was flown between the cathode and anode to perform the I-V measurement. Rectification was confirmed in 95 of the samples. Further, current was flown in the forward direction to confirm the luminescence of light of a wavelength of 460 nm.

(Test Results of Second Aspect)

It was grown the gallium nitride crystal layers of the respective comparative and inventive examples shown in table 2, the various characteristics were measured and the results were shown in table 2.

### Comparative Example A1

The comparative example A1 was same as that described above, except that the surface treatment of the seed crystal layer was not performed in the inventive example A1. On the surface of the seed crystal layer, the ratio of the C-plane was 100%. The number of dark spots and dislocation density on the surface of the thus obtained gallium nitride layer were measured, and shown in table 2.

### Inventive Examples B1 to B5 and Comparative Examples B1 to B5

The surface of the seed crystal substrate was subjected to the surface treatment as described above in the comparative example A1, and the gallium nitride crystal layer was grown thereon according to the same procedure as the comparative example A1.

Specifically, the surface of the seed crystal layer was subjected to chlorine plasma etching under the respective conditions shown in table 2. However, the conditions other than the etching time were made common, and etching times were made different for the respective samples.

As to the conditions of the chlorine plasma etching, the gas flow rate of the Cl₂ gas supplied into a chamber was made 35 sccm, the gas pressure in the chamber was made 1 Pa, and the ICP electric power supplied by a high frequency electric source was made 800 W. However, a bias voltage was not applied in the inventive examples and comparative examples B1 to B4, and the bias voltage was applied in the comparative example B5.

Further, for the respective samples, the surface convex-concave data was obtained in a region of 2 mm square by means of a laser microscope and the ratio of the C-plane was evaluated based on the results, before the film-formation of the gallium nitride layer.

The surface of the thus obtained gallium nitride layer was evaluated by eyes, so that the state of the formation of gallium nitride crystal was qualitatively evaluated (it was formed over the whole surface, or was formed over only a part of the surface, or not formed). As to the samples with the gallium nitride crystal formed, the cathode luminescence measurement was performed at an acceleration voltage of 15 kV and the dislocation density of the surface was calculated based on the thus obtained image.

### Comparative Example 6

A gallium nitride layer was grown as the inventive example B1, and the surface state was evaluated. However, in the comparative example B6, the alumina layer was not provided on the sapphire substrate, and the gallium nitride seed crystal layer was directly formed thereon. The similar test as the inventive example B1 was performed except them.

TABLE 2

| | | | | | Dislocation |
|---|---|---|---|---|---|
| | RIE time | Ratio of | Crystal | Substrate | density |
| | [min.] | C-plane [%] | growth | bias [W] | [/cm2] |
| Com. Ex. A1 | — | 100 | Whole surface | — | 3.4E+04 |
| Com. Ex. B1 | 20 | 81 | Whole surface | — | 3.1E+04 |
| Com. Ex. B2 | 60 | 71 | Whole surface | — | 2.3E+04 |
| Inv. Ex. B1 | 100 | 60 | Whole surface | — | 5.2E+03 |
| Inv. Ex. B2 | 120 | 52 | Whole surface | — | 3.7E+03 |
| Inv. Ex. B3 | 160 | 40 | Whole surface | — | 3.0E+03 |
| Inv. Ex. B4 | 200 | 30 | Whole surface | — | 2.2E+03 |
| Inv. Ex. B5 | 240 | 20 | Whole surface | — | 1.5E+03 |
| Com. Ex. B3 | 280 | 10 | Whole surface | — | 7.4E+02 |
| Com. Ex. B4 | 300 | 5 | A part | — | 7.4E+02 |
| Com. Ex. B5 | 30 | 40 | Whole surface | 100 | 1.9E+04 |
| Com. Ex. B6 | 150 | 55 | Whole surface | — | 7.5E+05 |

alumina layer is not present in comparative example B6

As described above, as the surface treatment of the second aspect of the present invention is combined with the seed crystal layer on the alumina layer and specific gallium nitride crystal layer, it was proved that considerable advantageous effect can be obtained. That is, the state of the crystal growth was good and the dislocation density was considerably reduced beyond expectation.

(Evaluation)

Then, the upper surfaces and bottom surfaces of the gallium nitride free-standing substrates of the respective inventive examples were subjected to polishing and subjected to the CL observation by means of a scanning type electron microscope (SEM) equipped with a CL detector. As a result, white light-emitting high-luminance light-emitting parts were confirmed inside of gallium nitride crystal based on the CL photograph. However, at the same time, as the same visual field was observed by the SEM, voids were not confirmed and uniform gallium nitride crystal was proved to be grown.

Further, the gallium nitride free-standing substrate was cut along a cross section perpendicular to the upper surface, and the cut cross section was subjected to polishing and the CL observation by means of a scanning type electron microscope (SEM) equipped with a CL detector. As a result, white light-emitting high-luminance light-emitting parts were confirmed inside of gallium nitride crystal based on the CL image. However, at the same time, as the same visual field was observed by the SEM, voids were not be confirmed and uniform gallium nitride crystal was proved to be grown. That is, at the cross section of the gallium nitride crystal layer, as the supper surface, the high-luminance light-emitting parts were present based on the CL observation, and microstructure having the same or similar shape as those of the high-luminance light-emitting parts shown in the CL photograph were not present in the same visual field based on the SEM.

(Film-Formation of Light-Emission Functional Layer by MOCVD Method)

By applying MOCVD method, on the upper surface of the gallium nitride free-standing substrate of the inventive example B1, it was deposited an n-GaN layer, which was doped at an Si atomic content of 5×10¹⁸/cm³, as an n-type layer at 1050° C. in 1 μm. Then, it was deposited a multiple quantum well layer at 750° C. as a light emitting layer. Specifically, five layers of well layers of 2.5 nm of InGaN and six layers of barrier layers of 10 nm of GaN were alternately deposited. Then, as a p-type layer, it was deposited p-type GaN in 200 nm at 950° C. doped so that an atomic concentration of Mg atoms became 1×10¹⁹/cm³. Thereafter, it was taken out of an MOCVD apparatus and then subjected to heat treatment at 800° C., in nitrogen atmosphere for 10 minutes as an activating treatment of Mg ions in the p-type layer.

(Production of Light-Emitting Device)

By photolithography process and vapor deposition method, on the surface on the opposite side of the n-GaN layer and p-GaN layer of the free-standing gallium nitride substrate, Ti film, Al film, Ni film and Au film were patterned in thicknesses of 15 nm, 70 nm, 12 nm and 60 nm, respectively as a cathode electrode. Thereafter, for improving ohm contact characteristic, heat treatment was performed at 700° C. for 30 seconds under nitrogen atmosphere. Further, by photolithography process and vapor deposition method, Ni film and Au film were patterned in thicknesses of 6 nm and 12 nm, respectively, as a transparent anode on the p-type layer. Thereafter, for improving the ohmic contact characteristic, heat treatment was performed at 500° C. for 30 seconds under nitrogen atmosphere. Further, by photolithography process and vapor deposition method, on a partial region of a top surface of the Ni and Al films as the transparent anode, Ni film and Au film were patterned in thicknesses of 5 nm and 60 nm, respectively, as a pad for the anode. The thus obtained substrate was cut into chips, which were mounted on lead frames to obtain light-emitting devices of vertical type structure.

(Evaluation of Light-Emitting Device)

Hundred samples were arbitrarily selected from the thus produced devices, and electricity was flown between the cathode and anode to perform the I-V measurement. Rectification was confirmed in 91 of the samples. Further, current was flown in the forward direction to confirm the luminescence of light of a wavelength of 460 nm.

(Experimental Results of Third Aspect) (Comparative Example A1)

The comparative example A1 was same as that described above, and the example in which the surface treatment of the seed crystal layer was not performed in the inventive example A1. The steps were not provided on the surface of the seed crystal layer. The dislocation density was measured on the surface of the thus obtained gallium nitride layer and shown in table 3.

### Inventive Examples C1 to C10 and Comparative Examples C1 to C4

After a gallium nitride underlying layer was film-formed on the alumina layer by HVPE method at 500° C., the seed crystal substrate and gallium nitride crystal layer were produced as the comparative example A1, except that the seed crystal layer 3 composed of gallium nitride and having a thickness of 350 μm was film-formed. However, at the stage of producing the seed crystal substrate, the surface of the seed crystal layer was processed by RIE (reactive ion etching) method, so that the steps having the terrace widths and height differences shown in table 3 were regularly formed. Further, the edges of the respective steps were made parallel with the a-plane or m-plane of the gallium nitride crystal. The terrace widths and positions of the steps and the directions of the edges of the steps were controlled by mask patterns during the RIE. The height differences (depths) of the steps were adjusted by the times of the treatment of the RIE.

The gallium nitride crystal layers were film-formed as the comparative example A1 on the thus obtained seed crystal substrates of the respective examples, and the dislocation densities of the surfaces were measured. The results were shown in table 3.

### Comparative Example C5

The gallium nitride crystal layer was grown as the inventive example C1, the surface state was evaluated. However, according to the comparative example C5, the alumina layer was not provided on the sapphire substrate, and the gallium nitride seed crystal layer was directly formed thereon. The test similar to that of the inventive example Cl was performed except them.

TABLE 3

| | | Terrace | | Dislocation |
|---|---|---|---|---|
| | Height | width | Parallel | density |
| | [um] | [mm] | surface | [/cm²] |
| Inv. Ex. C1 | 1 | 0.25 | a-plane | 7.4E+02 |
| Inv. Ex. C2 | 1 | 1 | a-plane | 1.5E+03 |
| Inv. Ex. C3 | 1 | 2 | a-plane | 2.2E+03 |
| Inv. Ex. C4 | 0.2 | 0.25 | a-plane | 3.0E+03 |
| Inv. Ex. C5 | 0.2 | 2 | a-plane | 6.0E+03 |
| Inv. Ex. C6 | 2 | 0.25 | a-plane | 4.5E+03 |
| Inv. Ex. C7 | 2 | 2 | a-plane | 5.2E+03 |
| Inv. Ex. C8 | 1 | 0.25 | m-plane | 2.2E+03 |
| Inv. Ex. C9 | 1 | 1 | m-plane | 3.0E+03 |
| Inv. Ex. C10 | 1 | 2 | m-plane | 3.7E+03 |
| Com. Ex. A1 | 0 | 0 | a-plane | 3.4E+04 |
| Com. Ex. C1 | 1 | 0.15 | a-plane | 8.9E+03 |
| Com. Ex. C2 | 1 | 3 | a-plane | 2.9E+04 |
| Com. Ex. C3 | 0.1 | 1 | a-plane | 3.5E+04 |
| Com. Ex. C4 | 3 | 1 | a-plane | 9.7E+03 |
| Com. Ex. C5 | 1 | 1 | a-plane | 2.7E+04 |

※ alumina layer was not present in comparative example C5

As described above, as the surface treatment of the third aspect of the present invention is combined with the seed crystal layer on the alumina layer and specific gallium nitride crystal layer, particularly considerable advantageous effect can be obtained. That is, the state of the crystal growth was good and dislocation density was considerably reduced beyond expectation.

(Evaluation)

Then, the upper surfaces and bottom surfaces of the gallium nitride free-standing substrates of the respective inventive examples were subjected to polishing and subjected to the CL observation by means of a scanning type electron microscope (SEM) equipped with a CL detector. As a result, white-light emitting high-luminance light emitting parts were confirmed inside of gallium nitride crystal based on the CL photograph. Further, at the same time, as the same visual field was confirmed by SEM observation, voids or the like were not confirmed and it was confirmed that uniform gallium nitride crystal was grown.

Further, the gallium nitride free-standing substrate was cut along a cross section perpendicular to the upper surface, and the cut cross section was subjected to polishing and the CL observation by means of a scanning type electron microscope (SEM) equipped with a CL detector. As a result, white light-emitting high-luminance light-emitting parts were confirmed inside of gallium nitride crystal based on the CL image. However, at the same time, as the same visual field was observed by the SEM, voids were not be confirmed and uniform gallium nitride crystal was proved to be grown. That is, at the cross section of the group 13 nitride crystal layer, as the upper surface, the high-luminance light-emitting parts were present based on the CL observation, and microstructure having the same or similar shape as that of the high-luminance light-emitting part shown in the CL photograph was not present in the same visual field based on the SEM.

(Film Formation of Light-Emitting Function Layer by MOCVD Method)

Applying MOCVD method, on the upper surface of the free-standing gallium nitride substrate of the inventive example A1, as a n-type layer, it was deposited an n-GaN layer in 1 μm at 1050° C. doped so that an atomic concentration of Si atoms became 5×10¹⁸/cm³. Then, as a light-emitting layer, it was deposited multiple quantum well layers at 750° C. Specifically, five layers of well layers of 2.5 nm of InGaN and six layers of barrier layers of 10 nm of GaN were alternately deposited. Then, as a p-type layer, it was deposited p-type GaN in 200 nm at 950° C. doped so that an atomic concentration of Mg atoms became 1×10¹⁹/cm³. Thereafter, it was taken out of an MOCVD apparatus and then subjected to heat treatment at 800° C. in nitrogen atmosphere for 10 minutes as an activating treatment of Mg ions in the p-type layer.

(Production of Light-Emitting Device)

By applying photolithography process and vacuum deposition method, Ti/Al/Ni/Au films a cathode were patterned on the surface on the side opposite to the n-GaN layer and p-GaN layer of the free-standing gallium nitride substrate in thicknesses of 15 nm, 70 nm, 12 nm, and 60 nm, respectively. Thereafter, to improve ohmic contact characteristics, heat treatment at 700° C. was performed in nitrogen atmosphere for 30 seconds. Furthermore, by applying photolithography process and vacuum deposition method, Ni/Au films were patterned as a translucent anode on the p-type layer in thicknesses of 6 nm and 12 nm, respectively. Thereafter, for improving the ohmic contact characteristic, heat treatment was performed at 500° C. for 30 seconds under nitrogen atmosphere. Further, by photolithography process and vapor deposition method, on a partial region of a top surface of the Ni and Al films as the transparent anode, Ni film and Au film were patterned in thicknesses of 5 nm and 60 nm, respectively, as a pad for the anode. The thus obtained substrate was cut into chips, which were mounted on lead frames to obtain light-emitting devices of vertical type structure.

(Evaluation of Light-Emitting Device)

Hundred samples were arbitrarily selected from the thus produced devices, and electricity was flown between the cathode and anode to perform the I-V measurement. Rectification was confirmed in 92 of the samples. Further, current was flown in the forward direction to confirm the luminescence of light of a wavelength of 460 nm.

1. A method of producing a group 13 nitride crystal layer, said method comprising:
a seed crystal layer growing step of providing a seed crystal layer comprising a group 13 nitride crystal selected from gallium nitride, aluminum nitride, indium nitride or the mixed crystals thereof, on an alumina layer on a single crystal substrate;
an annealing step of annealing said seed crystal layer under a reducing atmosphere at a temperature of 950° C. or higher and 1200° C. or lower to form a convex-concave morphology on a surface of said seed crystal layer having an RMS value of 180 nm to 700 nm measured by an atomic force microscope; and
a step of growing a group 13 nitride crystal layer comprising a group 13 nitride crystal selected from gallium nitride, aluminum nitride, indium nitride or the mixed crystals thereof, on said surface of said seed crystal layer.

2. The method of claim 1, wherein said reducing atmosphere comprises hydrogen gas and an inert gas in said annealing step.

3. The method of claim 1, wherein an upper surface of said group 13 nitride crystal layer comprises a linear high-luminance light-emitting part and a low-luminance light-emitting region adjacent to said high-luminance light emitting part, said upper surface being observed by cathode luminescence.

4. The method of claim 3, wherein said high-luminance light-emitting part comprises a part extending along an m-plane of said group 13 nitride crystal.

5. The method of claim 1, wherein a full width at half maximum of a (0002) plane reflection of an X-ray rocking curve on an upper surface of said group 13 nitride crystal layer is 3000 seconds or smaller and 20 seconds or larger.

6. The method of claim 1, wherein a void is not observed in a cross section substantially perpendicular to an upper surface of said group 13 nitride crystal layer.

7. The method of claim 3, wherein said high-luminance light-emitting part forms a continuous phase and wherein said low-luminance light-emitting region forms a discontinuous phase divided by said high-luminance light-emitting part.

8. The method of claim 1, wherein a full width at half maximum of a (1000) plane reflection of an X-ray rocking curve on an upper surface of said group 13 nitride crystal layer is 10000 seconds or smaller and 20 seconds or larger.

9. The method of claim 1, further comprising the step of separating said single crystal substrate from said group 13 nitride crystal layer after said group 13 nitride crystal layer is grown, to obtain a free-standing substrate comprising said group 13 nitride crystal layer.

10. A method of producing a group 13 nitride crystal layer, said method comprising:
a seed crystal layer growing step of providing a seed crystal layer comprising a group 13 nitride crystal selected from gallium nitride, aluminum nitride, indium nitride or the mixed crystals thereof, on an alumina layer on a single crystal substrate;
an etching step of etching a surface of said seed crystal layer by chlorine plasma etching to form recesses on said surface so that a ratio of C-plane is 10% or larger and 60% or smaller while said surface of said seed crystal layer is etched without a bias voltage applied on said seed crystal layer; and
a step of growing a group 13 nitride crystal layer comprising a group 13 nitride crystal selected from gallium nitride, aluminum nitride, indium nitride or the mixed crystals thereof, on said surface of said seed crystal layer.

11. The method of claim 10, wherein an upper surface of said group 13 nitride crystal layer comprises a linear high-luminance light-emitting part and a low-luminance light-emitting region adjacent to said high-luminance light emitting part, said upper surface being observed by cathode luminescence.

12. The method of claim 11, wherein said high-luminance light-emitting part comprises a part extending along an m-plane of said group 13 nitride crystal.

13. The method of claim 10, wherein a full width at half maximum of a (0002) plane reflection of an X-ray rocking curve on an upper surface of said group 13 nitride crystal layer is 3000 seconds or smaller and 20 seconds or larger.

14. The method of claim 10, wherein a void is not observed in a cross section substantially perpendicular to an upper surface of said group 13 nitride crystal layer.

15. The method of claim 11, wherein said high-luminance light-emitting part forms a continuous phase and wherein said low-luminance light-emitting region forms a discontinuous phase divided by said high-luminance light-emitting part.

16. The method of claim 10, wherein a full width at half maximum of a (1000) plane reflection of an X-ray rocking curve on an upper surface of said group 13 nitride crystal layer is 10000 seconds or smaller and 20 seconds or larger.

17. The method of claim 10, further comprising the step of separating said single crystal substrate from said group 13 nitride crystal layer after said group 13 nitride crystal layer is grown, to obtain a free-standing substrate comprising said group 13 nitride crystal layer.

18. A seed crystal substrate comprising:
a single crystal substrate;
an alumina layer on said single crystal substrate; and
a seed crystal layer provided on said alumina layer and comprising a group 13 nitride crystal selected from gallium nitride, aluminum nitride, indium nitride or the mixed crystals thereof,
wherein a surface of said seed crystal layer comprises a plurality of steps,
wherein heights of said steps are 0.2 to 2p m, and
wherein terrace widths of said steps are 0.25 to 2.0 mm.

19. A method of producing a group 13 nitride crystal layer, said method comprising the step of:
growing a group 13 nitride crystal layer comprising a group 13 nitride crystal selected from gallium nitride, aluminum nitride, indium nitride or the mixed crystals thereof, on said surface of said seed crystal layer of the seed crystal substrate of claim 18.

20. The method of claim 19, wherein said steps comprises edges which are formed substantially in parallel with an a-plane of said group 13 nitride crystal.

21. The method of claim 19, wherein an upper surface of said group 13 nitride crystal layer comprises a linear high-luminance light-emitting part and a low-luminance light-emitting region adjacent to said high-luminance light emitting part, said upper surface being observed by cathode luminescence.

22. The method of claim 21, wherein said high-luminance light-emitting part comprises a part extending along an m-plane of said group 13 nitride crystal.

23. The method of claim 19, wherein a full width at half maximum of a (0002) plane reflection of an X-ray rocking curve on an upper surface of said group 13 nitride crystal layer is 3000 seconds or smaller and 20 seconds or larger.

24. The method of claim 19, wherein a void is not observed in a cross section substantially perpendicular to an upper surface of said group 13 nitride crystal layer.

25. The method of claim 21, wherein said high-luminance light-emitting part forms a continuous phase and wherein said low-luminance light-emitting region forms a discontinuous phase divided by said high-luminance light-emitting part.

26. The method of claim 19, wherein a full width at half maximum of a (1000) plane reflection of an X-ray rocking curve on an upper surface of said group 13 nitride crystal layer is 10000 seconds or smaller and 20 seconds or larger.

27. The method of claim 19, further comprising the step of separating said group 13 nitride crystal layer from said surface of said seed crystal layer of said seed crystal substrate, to obtain a free-standing substrate comprising said group 13 nitride crystal layer.
